(19) United States
(12) Patent Application Publication
(10) Pub. No.: US 2025/0239279 A1
(43) Pub. Date: Jul. 24, 2025

(54) MEMORY DEVICE AND METHOD OF CONTROLLING EQUIVALENT RESISTANCE OF BIT LINE OR SOURCE LINE CORRESPONDING TO WORD LINE OF THE MEMORY DEVICE

(71) Applicant: United Microelectronics Corp., Hsinchu (TW)

(72) Inventors: Chin-Hsun Yeh, Tainan City (TW); Min Chia Wang, New Taipei City (TW)

(73) Assignee: United Microelectronics Corp., Hsinchu (TW)

(21) Appl. No.: 18/430,585

(22) Filed: Feb. 1, 2024

(30) Foreign Application Priority Data
Jan. 18, 2024 (TW) 113102000

(51) Int. Cl. G11C 7/02; G11C 7/12; G11C 8/10

(52) U.S. Cl. CPC G11C 7/02; G11C 7/12; G11C 8/10

(57) ABSTRACT

According to an exemplary embodiment, the disclosure provides a memory device which includes but not limited to a memory array including a plurality of memory cells, a first terminal of each of the plurality of memory cells is connected to a bit line, a second terminal of each of the plurality of memory cells is connected to a source line, and a third terminal of each of the plurality of memory cells is connected to a word line, wherein the word line is associated with a word line address, and a resistance trimming circuit connected to either the source line, the bit line or a common source line and configured to receive a trimming code to change an equivalent resistance of the source line or the bit line based on the trimming code, wherein the trimming code is tied to the word line address.

### CROSS-REFERENCE TO RELATED APPLICATION

This application claims the priority benefit of Taiwan application serial no. 113102000, filed on Jan. 18, 2024. The entirety of the above-mentioned patent application is hereby incorporated by reference herein and made a part of specification.

### TECHNICAL FIELD

The disclosure is directed to memory device and a method of controlling an equivalent resistance of a bit line or a source line corresponding to a word line of the memory device.

### BACKGROUND

All memory devices have a memory array containing multiple memory cells, each of the memory cells typically has an active device for accessing the content of the memory cell. Such active device could be implemented, for example, by using a field effect transistor (FET) having three terminals including a drain terminal connected to a bit line (BL), a source terminal connected to a source line (SL), and a gate terminal connected to a word line (WL).

However, for different WLs, the lengths of BL and SL could be different. Also, BLs and SLs could be disposed in different metal layers and have different widths and line spacings resulting in different equivalent resistance values per unit length of BL and SL. Consequently, for memory cells located in different WLs, the equivalent resistance of the SL or the BL at or near each memory cell could be different causing variations of write voltages across memory cells in different WLs. Due to the variations of write voltages across memory cells in different WLs, some memory cells may experience higher voltages than intended, and such higher voltage may cause errors during a write operation.

Therefore, a memory device may benefit from a mechanism to control the equivalent resistance of a SL or a BL at different WL locations.

### SUMMARY OF THE DISCLOSURE

Accordingly, the disclosure is directed to memory device and a method of controlling an equivalent resistance of a BL or a SL corresponding to a WL of the memory device.

An aspect of the disclosure is directed to a memory device which includes but not limited to a memory array comprising a plurality of memory cells, a first terminal of each of the plurality of memory cells is connected to a BL, a second terminal of each of the plurality of memory cells is connected to a SL, and a third terminal of each of the plurality of memory cells is connected to a WL, wherein the WL is associated with a word line address, and a resistance trimming circuit connected to either the SL or the BL and configured to receive a trimming code to change an equivalent resistance of the SL or the BL based on the trimming code, wherein the trimming code is tied to the word line address.

Another aspect of the disclosure is directed to a method of controlling an equivalent resistance of a BL or a SL corresponding to a WL of a memory device, wherein a first terminal of each of a plurality of memory cells is connected to a bit line, a second terminal of each of the plurality of memory cells is connected to a source line, and a third terminal of each of the plurality of memory cells is connected to a WL. The method includes but not limited to: receiving a trimming code which is tied to a word line address; activating or deactivating each resistor of a plurality of resistors of a resistance trimming circuit connected to either the SL or the BL based on the trimming code to change the equivalent resistance of the SL or the BL, and activating or deactivating the plurality of memory cells of a WL according to the word line address.

In order to make the aforementioned features and advantages of the present disclosure comprehensible, exemplary embodiments accompanied with figures are described in detail below. It is to be understood that both the foregoing general description and the following detailed description are exemplary, and are intended to provide further explanation of the disclosure as claimed.

It should be understood, however, that this summary may not contain all of the aspect and embodiments of the present disclosure and is therefore not meant to be limiting or restrictive in any manner. Also, the present disclosure would include improvements and modifications which are obvious to one skilled in the art.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 illustrates a hardware diagram of a memory array within a memory device according to an exemplary embodiment of the disclosure.

FIG. 2 illustrates memory cells connected to different WLs having different write voltages according to an exemplary embodiment of the disclosure.

FIG. 3 illustrates memory cells connected to different WLs having different write voltages according to an exemplary embodiment of the disclosure.

FIG. 4 illustrates a resistance trimming circuit according to an exemplary embodiment of the disclosure.

FIG. 5 illustrates a resistance trimming circuit connected to a SL according to an exemplary embodiment of the disclosure.

FIG. 6 illustrates a resistance trimming circuit connected to a common SL according to an exemplary embodiment of the disclosure.

FIG. 7 illustrates an example of utilizing resistance trimming circuits for a memory array having 512 WLs according to an exemplary embodiment of the disclosure.

FIG. 8 illustrates an experimental result which is able to show a reduction of variations of write voltages across memory cells in different word lines according to an exemplary embodiment of the disclosure.

FIG. 9 is a flow chart which illustrates controlling an equivalent resistance of a BL or a SL of a memory array according to an exemplary embodiment of the disclosure.

### DETAILED DESCRIPTION OF DISCLOSED EMBODIMENTS

Reference will now be made in detail to the present exemplary embodiments of the disclosure, examples of which are illustrated in the accompanying drawings. Wherever possible, the same reference numbers are used in the drawings and the description to refer to the same or like parts.

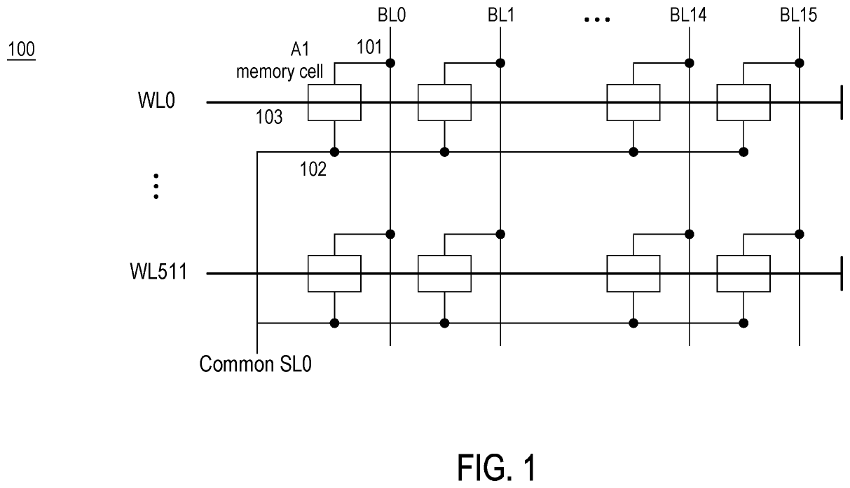

FIG. 1 shows a hardware diagram of a memory array 100 within a memory device. The memory array contains multiple memory cells, multiple BLs, multiple WLs, and multiple SLs. Take the memory cell A1 as an example, the memory cell A1 could be a FET having three terminals including a first terminal 101 connected to a BL (e.g. BL0), a second terminal 102 connected to a SL source line (SL0), and a third terminal 103 connected to a WL (e.g. WL0). Each of the WLs is associated with a unique word line address. The first terminal could be a drain terminal of the FET, the second terminal could be a source terminal of the FET, and the third terminal could be a gate terminal of the FET.

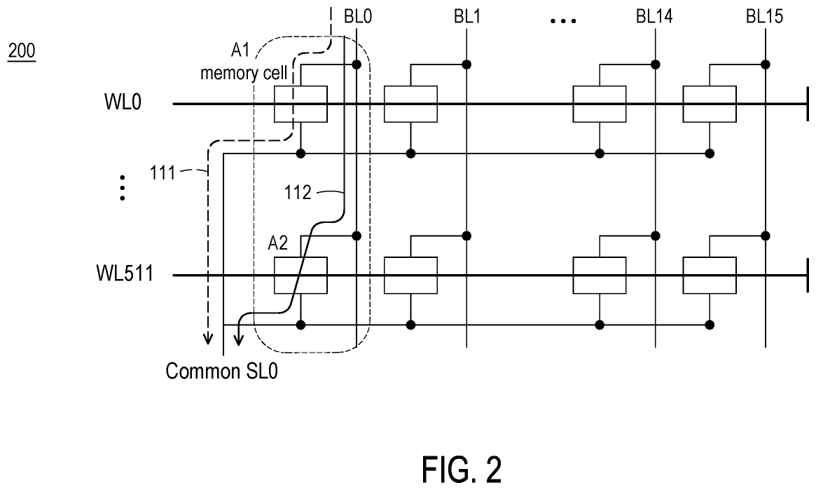

Assuming that the SLs are connected to ground, the lengths of current paths for memory cells in different WLs are different. Referring to FIG. 2, the memory cell A1 has a first current path 111 which is from BL0 and is across A1 to the SL. Similar, the memory cell A2 has a second current path 112 which is from BL0 and is across the memory cell A2 to the SL. However, since the resistance per unit line length could be different for each SL and BL, the write voltage at A1 (or across the memory cell A1) could be different from the write voltage at the memory cell A2. One of the aims of the disclosure is to minimize the variation of write voltages among the memory cells (e.g. between the memory cells A1 and A2) located in different WLs.

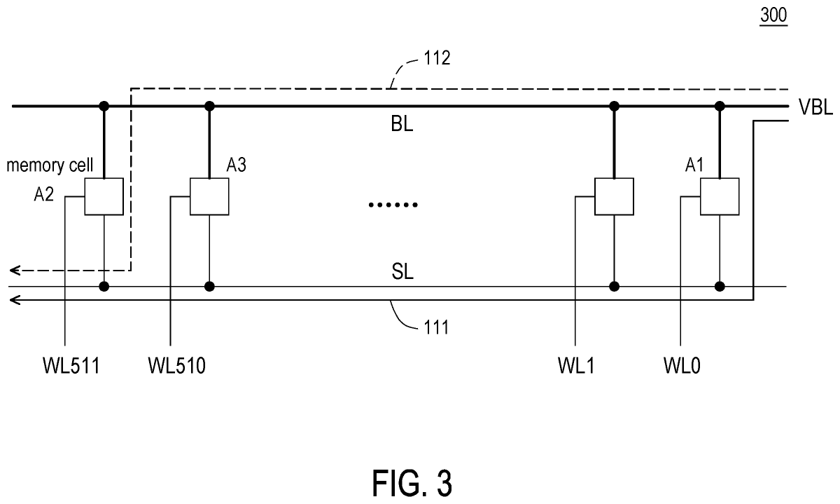

A circuit diagram that is similar to FIG. 2 is shown in FIG. 3 in which the memory cell A1 on WL0 is situated on the first current path 111 and the memory cell A2 on WL511 is situated on the second current path 112. During a write operation, the equivalent resistance of the BL or SL perceived by the memory cell A1 at WL0 would be different from the equivalent resistance of the BL or SL perceived by the memory cell A2 at WL511 because of the inevitable layout differences between BL and SL as previously described. Thus, the voltage drop across the memory cell A1 would be different from the voltage drop across the memory cell A2. In order to resolve this issue, the disclosure provides a resistance trimming circuit which is connected to either a SL or a BL in order for memory cells at different WLs or a group of different WLs to perceive the same or similar equivalent resistance of the BL or the SL. The resistance trimming circuit could be located in a SL driver or a BL driver. The resistance trimming circuit could be connected to a SL or a BL that is shared by a group of WLs. Alternatively, the resistance trimming circuit could be connected to a SL or a BL of each of the WLs.

Inventive concepts are further described as follows. Each resistance trimming circuit may receive a trimming code. The trimming code could be unique for each of the resistance trimming circuit. The trimming code could be input by decoding from the WL address of the corresponding WL via a decoder circuit (e.g. the WL address decoder 401). Assuming that a resistance trimming circuit is connected to a SL or a BL corresponding to a WL which has a WL address of X bits, the trimming code is most significant Y bits of the X bits, Y≤X, where Y is a number of resistors in the resistance trimming circuit. A number of where 2 to the X^{th} power of bit lines are grouped into a number of 2 to the (X−Y)^{th} Power. The trimming code uses a combination divided into 2 to the Y^{th} Power to perform fine-tuning.

As a concrete example, it is assumed that there are 512 WLs in an memory array, and each WL has a unique WL address of 9 binary bits. Also, assuming that 512 WLs would be grouped in to 8 group by a resistance trimming circuit composed of Y trimming switches and Y resistors, then Y equals 3 since 2 to the Y^{th} power equals 8. In this way, the most significant Y=3 bits of the X bits would be the trimming code. To realize inventive concepts as described, the disclosure provides exemplary embodiments explained as follows.

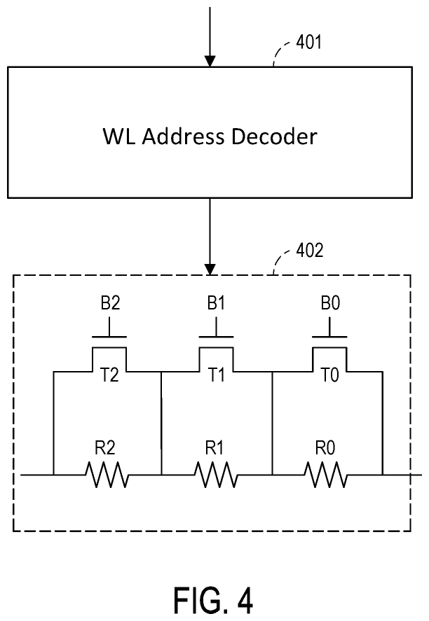

An embodiment of the above-described resistance trimming circuit 402 is shown in FIG. 4. The resistance trimming circuit 402 includes multiple trimming switches including trimming switches T0, T1, and T2, and the resistance trimming circuit 402 also includes multiple resistors including resistors R0, R1, and R2, each of the trimming switches T0, T1, T2 is turned on or off according to the trimming code B0 B1 B2 which is received from a WL address decoder 401 and corresponds to a value of the most significant Y bits of the X bits of the word line address to deactivate or activate a corresponding resistor of the plurality of resistors. To be more concrete, the WL address decoder 401 would receive a WL address of a WL which could be a part of a group of WLs which share the same resistance trimming circuit 402 by connecting to a common SL. The WL address decoder 401 would then output the most significant Y bits of the X bits as the trimming code B0 B1 B2. Upon receiving the trimming code, each of the trimming codes B0, B1, B2 would turn on or turn off its corresponding trimming switches T0, T1, T2.

For example, if the trimming code B0 is a binary 1, first transistor TO is turned on to bypass the first resistor R0. If the trimming code B0 is a binary 0, the first transistor TO is turned off and the resistance of the first resistor R0 is added to the equivalent resistance of the SL assuming that the resistance trimming circuit 402 is connected to the SL instead of the BL. However, the same principle applies if the resistance trimming circuit 402 is connected to the BL. Also, the same operating principle as described for the trimming code B0 also applies for the trimming code B1 and the trimming code B2. Assuming that the trimming code is 1 1 1, then none of the resistors R0 R1 R2 is added to the equivalent resistance of the SL. Assuming that the trimming code is 000, then all of the resistors R0 R1 R2 are added to the equivalent resistance of the SL.

In the case where the resistance trimming circuit 402 is connected to a SL, then the resistor R0 is connected to the SL, the resistor R1 is connected to the resistor R0 in series, and the resistor R2 is connected the resistor R1 in one terminal and connected to the SL driver on the other terminal. The trimming switch TO is connected to the resistor R0 in parallel. The trimming switch T1 is connected to the trimming switch T0 and connected to the resistor R1 in parallel. The trimming switch T2 is connected to the resistor R2 in parallel.

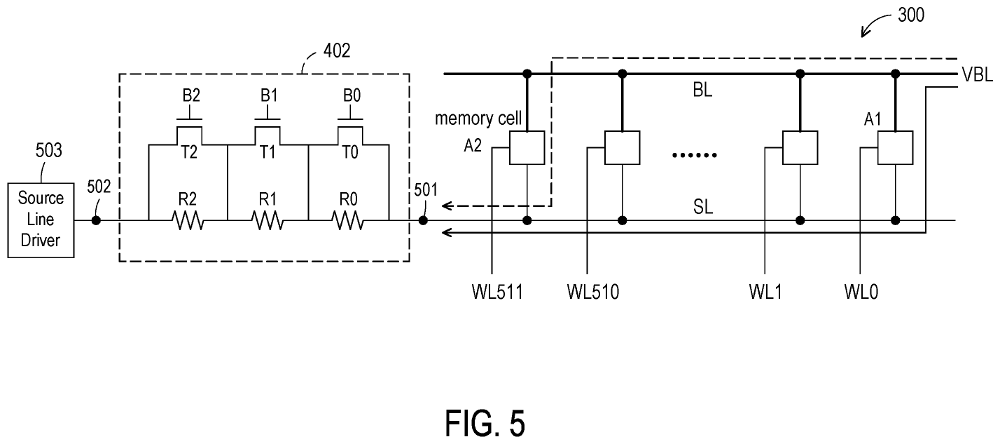

FIG. 5 shows a circuit diagram of a resistance trimming circuit 402 connected to a SL. As shown in FIG. 5, one terminal 501 of the resistance trimming circuit 402 is connected to the SL and another terminal 502 of the resistance trimming circuit 402 is connected to a source line driver 503, so as to affect the equivalent resistance of the source line SL sensed by the memory cells A1, A2.

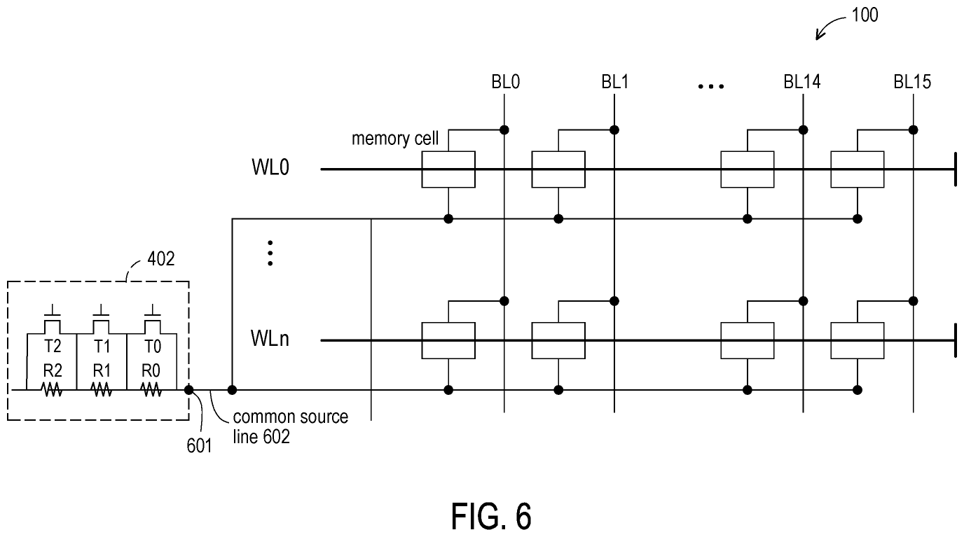

Similar to the embodiment of FIG. 5, FIG. 6 shows the resistance trimming circuit 402 connected to a common SL. The SL typically serves as a common ground of the memory array of a memory device, and the SLs serving different columns or rows of WLs could be connected to form a common SL. As shown in FIG. 6, one terminal 601 of the resistance trimming circuit 402 is connected to the common SL and another terminal could be connected to the source driver (e.g. the source line driver 503 in FIG. 5).

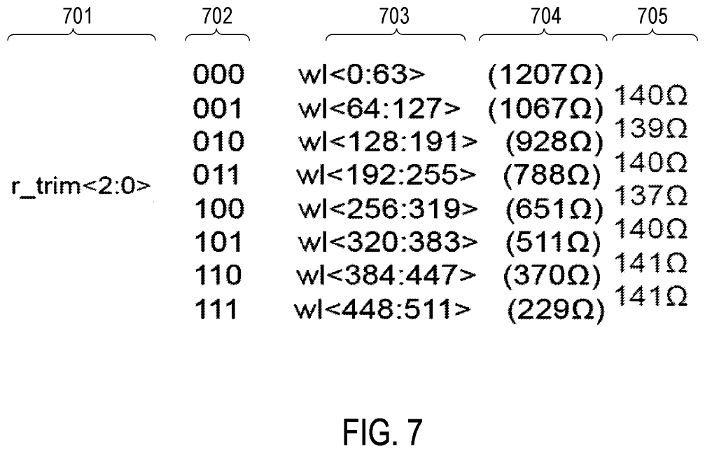

FIG. 7 shows an example of utilizing resistance trimming circuits for a memory array having 512 WLs. The first column 701 of FIG. 7 shows that a trimming code utilized for a memory array having 512 WLs. Since there are 8 groups of WLs as shown in the second column 702 of FIG. 7, each of the 8 groups is represented by 3 binary digits of different values, and the 3 binary digits also correspond to each of different trimming codes. As 512 WLs require X=9 binary digits to represent, each of the trimming codes of the resistance trimming circuit also corresponds to the first Y=3 most significant bits of the X=9 binary bits of the WL address of each WL. This means that each of level of the resistance trimming circuit 701 is shared by the SL of 512/8=64 WLs as shown in the third column 703 of FIG. 7. The fourth column 704 shows the increasing equivalent resistance of the SL corresponding to the group of WLs of the third column 703 of FIG. 7. The fifth column 705 shows the increase of equivalent resistance of SLs between each group of WLs due to the use of the resistance trimming circuit.

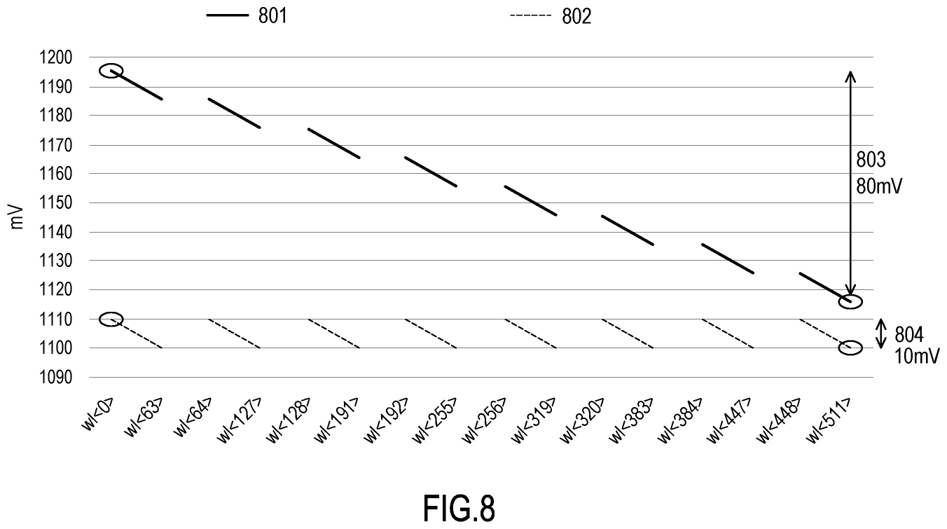

An experiment has been performed to demonstrate the reduction of the variations among write voltages across memory cells in different WLs, and the experimental result is shown in FIG. 8. As seen in FIG. 8, the first set of data 801 is the writing voltage across each memory cell of 512 WLs without using any resistance trimming circuit and the second data of data 802 is the writing voltage across each memory cell of 512 WLs by using the resistance trimming circuit (e.g. 402) as previously disclosed. For the first set of data 801, a writing voltage difference 803 between the writing voltage across a memory cell of the first WL and the writing voltage across a memory cell of the 512th WL is as high as 80 millivolt (mV). For the second set of data 802, a writing voltage difference 804 between the writing voltage across the memory cell of the first WL and the writing voltage across the memory cell of the 512th WL is reduced to a maximum of about 10 mV. Therefore, there is a clear reduction of the variations among the writing voltage across memory cells of different WLs.

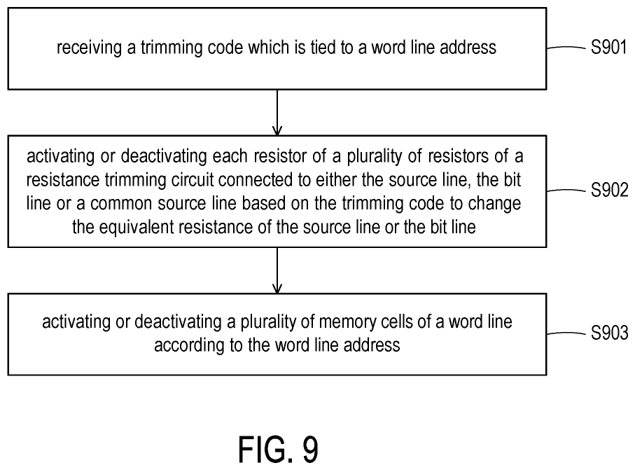

FIG. 9 is a flow chart which illustrates a method of controlling an equivalent resistance of a bit line or a source line of a memory array according to an exemplary embodiment of the disclosure. a first terminal of each of a plurality of memory cells of the memory array is connected to a BL, a second terminal of each of the plurality of memory cells is connected to a SL, and a third terminal of each of the plurality of memory cells is connected to a WL. In step S901, a resistance trimming circuit of the memory array of the memory device would receive a trimming code which is tied to the WL address. In step S902, the resistance trimming circuit would either deactivate or activate each resistor of a plurality of resistors of a resistance trimming circuit connected to either the SL, the BL or the common SL based on the trimming code to change the equivalent resistance of the SL or the BL corresponding to the WL. In step S903, the memory device would activate or deactivate the plurality of memory cells of the WL according to the WL address via the memory controller.

In the case in which the WL address has X bits, the trimming code would be the most significant Y bits of the X bits, Y≤X, and X and Y are integers greater than 0. Also, each of the resistance trimming circuit has a maximum of Y trimming switches and Y resistors, where each of the Y trimming transistors is able to turn on or off one of its corresponding resistor.

In view of the aforementioned-descriptions, the present disclosure is suitable for being used in any memory device and is able to adjust the equivalent BL resistance or the equivalent SL resistance at a WL so that the variations among write voltages across memory cells in different WLs are minimized.

No element, act, or instruction used in the detailed description of disclosed embodiments of the present application should be construed as absolutely critical or essential to the present disclosure unless explicitly described as such. Also, as used herein, each of the indefinite articles “a” and “an” could include more than one item. If only one item is intended, the terms “a single” or similar languages would be used. Furthermore, the terms “any of” followed by a listing of a plurality of items and/or a plurality of categories of items, as used herein, are intended to include “any of”, “any combination of”, “any multiple of”, and/or “any combination of multiples of” the items and/or the categories of items, individually or in conjunction with other items and/or other categories of items. Further, as used herein, the term “set” is intended to include any number of items, including zero. Further, as used herein, the term “number” is intended to include any number, including zero.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A memory device comprising
a memory array comprising a plurality of memory cells, a first terminal of each of the plurality of memory cells is connected to a bit line, a second terminal of each of the plurality of memory cells is connected to a source line, and a third terminal of each of the plurality of memory cells is connected to a word line, wherein the word line is associated with a word line address, and
a resistance trimming circuit connected to either the source line, the bit line or a common source line and configured to receive a trimming code to change an equivalent resistance of the source line or the bit line based on the trimming code, wherein the trimming code is tied to the word line address.

2. The memory device of claim 1, wherein the word line address has X bits, the trimming code is most significant Y bits of the X bits, and Y≤X, wherein X and Y are integers greater than 0.

3. The memory device of claim 2, wherein the resistance trimming circuit comprising a plurality of trimming switches and a plurality of resistors, each of the plurality of trimming switches is turned on or off according to the trimming code which corresponds to a value of the most significant Y bits of the X bits of the word line address to deactivate or activate a corresponding resistor of the plurality of resistors.

4. The memory device of claim 3, wherein a quantity of the plurality of trimming switches is equal to Y.

5. The memory device of claim 4, wherein a quantity of the plurality of resistors is the same as the quantity of the plurality of trimming switches.

6. The memory device of claim 3, wherein the plurality of resistors comprising:
a first resistor connected to either the source line or the bit line, and
a second resistor connected to the first resistor in series, and
the plurality of trimming switches comprising:
a first trimming switch connected to the first resistor in parallel, and
a second trimming switch connected to the second resistor in parallel.

7. The memory device of claim 6, wherein in response to at least the first trimming switch and the second trimming switch having been deactivated by the trimming code, the equivalent resistance of the bit line or the source line increases by at least a first resistance of the first resistor in addition to a second resistance of the second resistor.

8. The memory device of claim 3 further comprises a word line address decoder which provides the trimming code which decodes the word line address to obtain the most significant Y bits of the X bits of the word line address as the trimming code.

9. The memory device of claim 1, wherein one terminal of the resistance trimming circuit is connected to the source line and another terminal of the resistance trimming circuit is connected to a source line driver.

10. The memory device of claim 1, wherein the resistance trimming circuit is connected to the common source line.

11. A method of controlling an equivalent resistance of a bit line or a source line connected to a plurality of memory cells of a memory device, wherein a first terminal of each of the plurality of memory cells is connected to the bit line, a second terminal of each of the plurality of memory cells is connected to the source line, and a third terminal of each of the plurality of memory cells is connected to a word line, the method comprising:
receiving a trimming code which is tied to a word line address;
activating or deactivating each resistor of a plurality of resistors of a resistance trimming circuit connected to either the source line, the bit line or a common source line based on the trimming code to change the equivalent resistance of the source line or the bit line; and
activating or deactivating the plurality of memory cells of a word line according to the word line address.

12. The method of claim 11, wherein the word line address has X bits, the trimming code is most significant Y bits of the X bits, and Y≤X, wherein X and Y are integers greater than 0.

13. The method of claim 12, wherein activating or deactivating each resistor of the plurality of resistors of the resistance trimming circuit comprising:
turning on or off each of a plurality of trimming switches and the plurality of resistors of the resistance trimming circuit according to the trimming code which corresponds to a value of the most significant Y bits of the X bits of the word line address to deactivate or activate a corresponding resistor of the plurality of resistors.

14. The method of claim 13, wherein a quantity of the plurality of trimming switches is equal to Y.

15. The method of claim 14, wherein a quantity of the plurality of resistors is the same as the quantity of the plurality of trimming switches.

16. The method of claim 13, wherein plurality of resistors comprising:
a first resistor connected to either the source line or the bit line, and
a second resistor connected to the first resistor in series, and
the plurality of trimming switches comprising:
a first trimming switch connected to the first resistor in parallel, and
a second trimming switch connected to the second resistor in parallel.

17. The method of claim 16 further comprising:
increasing the equivalent resistance of the bit line or the source line by at least a first resistance of the first resistor in addition to a second resistance of the second resistor in response to at least the first trimming switch and the second trimming switch having been deactivated by the trimming code.

18. The method of claim 13 further comprising:
providing the trimming code from a word line address decoder which decodes the word line address to obtain the most significant Y bits of the X bits of the word line address as the trimming code.

19. The method of claim 11, wherein one terminal of the resistance trimming circuit is connected to the source line and another terminal of the resistance trimming circuit is connected to a source line driver.

20. The method of claim 11, wherein the resistance trimming circuit is connected to the common source line.
